(19) United States
(12) Patent Application Publication
(10) Pub. No.: US 2026/0126589 A1
(43) Pub. Date: May 7, 2026

(54) CO-PACKAGED OPTICS SYSTEMS THAT INCLUDE OPTICAL ENGINES AND METHODS OF MAKING THE SAME

(71) Applicant: Taiwan Semiconductor Manufacturing Company Limited, Hsinchu (TW)

(72) Inventors: Wei-kang Liu, Taichung City (TW); Cheng-Tse Tang, Hsinchu (TW); Hau-Yan Lu, Hsinchu City (TW); Chun-Heng Chen, Hsinchu City (TW); I-Chun Wang, Taichung City (TW); Tsung-Hsueh Yang, Taichung City (TW); Lee-Chuan Tseng, New Taipei City (TW)

(21) Appl. No.: 18/935,900

(22) Filed: Nov. 4, 2024

(51) Int. Cl. G02B 6/136; G02B 6/122

(52) U.S. Cl. CPC G02B 6/136; G02B 6/1228

(57) ABSTRACT

Optical engines and methods for fabricating optical engines. In embodiments, the optical engine includes a silicon substrate and a photonic component mounted on the silicon substrate. The photonic component includes an edge coupler and a coupling interface configured to interface with one or more external optical components. The edge coupler includes a photonic component edge at the coupling interface. The silicon substrate includes a substrate coupling edge at the coupling interface. The photonic component edge protrudes beyond the substrate coupling edge at the coupling interface.

### BACKGROUND

Silicon photonics technology may be useful for high-speed data transmission and optical communication systems. One of the components in some of these optical communication systems is the edge coupler, which facilitates the efficient transfer of optical signals between silicon photonics devices of the optical communication system and external optical elements. These external elements typically include, for example, a fiber array unit (FAU) or a micro-optics lens, which may be used for directing and focusing the optical signals into and out of the silicon photonics chip. The integration of an effective edge coupler may aid in minimizing coupling losses and ensuring high-performance operation of the entire optical communication system.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1G illustrate an example co-packaged optics system including an embodiment optical engine.

FIGS. 2A-2B are a vertical cross-sectional views of an alternative embodiment configuration for the optical engine.

FIG. 3A-3E illustrate various intermediate structures that may be formed and used in an embodiment process for fabricating an optical engine having an edge coupler.

FIGS. 4A-4E illustrate various intermediate structures that may be formed and used in an embodiment process for fabricating an optical engine having an edge coupler with a silicon nitride (SiN) spot size converter.

FIGS. 5A-5D illustrate various intermediate structures that may be formed and used in another embodiment process for fabricating an optical engine having an edge coupler.

FIGS. 6A-6D illustrate various intermediate structures that may be formed and used in another embodiment process for fabricating an optical engine having an edge coupler.

FIGS. 7A-7D illustrate elements of an embodiment optical engine after removal of a silicon ledge.

FIGS. 8A-8B illustrate various intermediate structures that may be formed and used in an embodiment process for aligning an edge coupler with an example optical component.

FIG. 9 illustrates a flow diagram of an embodiment method for fabricating an optical engine.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range. Various embodiments will be described in detail with reference to the accompanying drawings. Wherever possible, the same reference numbers will be used throughout the drawings to refer to the same or like parts. References made to particular examples and implementations are for illustrative purposes and are not intended to limit the scope of the claims.

The fabrication of edge couplers in silicon photonics may present several technical challenges. These technical challenges include achieving precise alignment between the silicon waveguide and the external optical elements, as well as maintaining low insertion loss and high coupling efficiency over a broad wavelength range. Various methods have been proposed to address these issues, including tapered waveguides, grating couplers, and butt-coupling techniques. However, each approach has its own challenges in terms of fabrication complexity, alignment tolerance, and overall coupling performance.

The proximity of the edge coupler to external optical components, such as a fiber array unit (FAU) or a micro-optics lens system, is a factor influencing the efficiency and performance of silicon photonics systems. Close positioning of the edge coupler to these components may be useful for minimizing optical insertion loss and maximizing coupling efficiency. The close positioning of the edge coupler to these components results in a reduction in spacing, which helps to ensure that the optical signal may be transferred with minimal divergence and attenuation, thereby preserving signal integrity. However, achieving such proximity and close positioning may pose technical challenges, particularly in terms of precise alignment and mechanical stability.

In optical engines designed for co-packaged optics, a residual silicon ledge may remain after the photonic integrated circuit (PIC) chip is diced. This residual silicon ledge imposes a constraint on the minimum achievable spacing between the edge coupler and the fiber array unit (FAU) or the micro-optics lens system. The presence of this silicon ledge may adversely impact the alignment precision and coupling efficiency, as the silicon edge prevents the edge coupler from being positioned in optimal proximity to the external optical components.

In some embodiments, a device incorporates an edge coupler fabricated on a silicon substrate, designed to enhance the coupling efficiency with external optical components such as a fiber array unit (FAU) or a micro-optics lens system. The edge coupler may be integrated into the silicon substrate through photolithography and etching processes. To achieve closer proximity to the external optical components, specific portions of the silicon substrate may be selectively removed. This removal process involves precise etching techniques that create a recess in the substrate around the edge coupler. In some embodiments, the recess may create space for subsequent dicing to be performed while maintaining a safe distance from the edge coupler.

After the selective etching, the substrate may be diced to allow the edge coupler to protrude beyond the physical boundary of the remaining substrate. This protrusion enables the edge coupler to be positioned closer to the external optical components, thereby reducing the optical path length and potential signal loss. The reduction in spacing between the edge coupler and the external components facilitates improved alignment and coupling efficiency, as the optical signal may be transferred with less divergence and attenuation.

The process of substrate removal and dicing may be controlled to maintain the structural integrity and alignment precision of the edge coupler. By allowing the edge coupler to protrude, the design mitigates the limitations imposed by the residual silicon ledge, which typically constrains the minimum spacing between the edge coupler and the external optical components. This approach may enhance the overall performance of the optical coupling system, making it more suitable for high-density and high-performance silicon photonics applications.

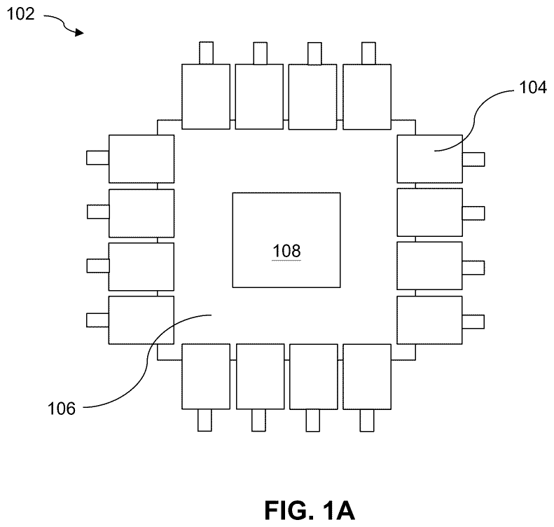

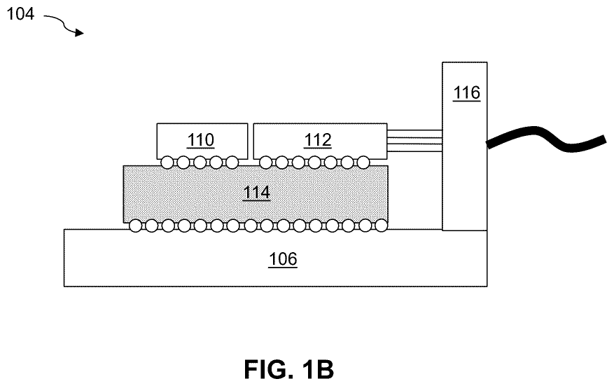

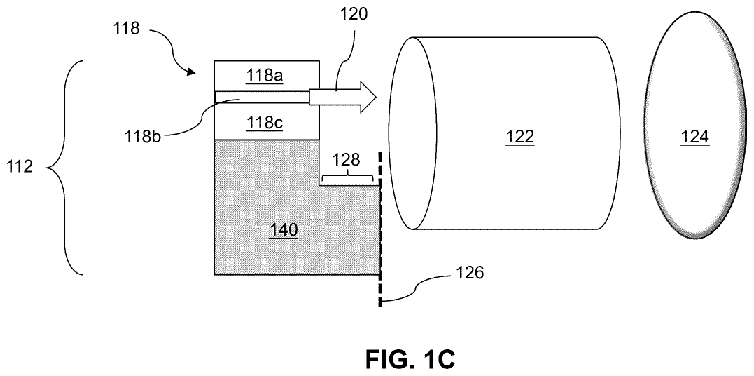

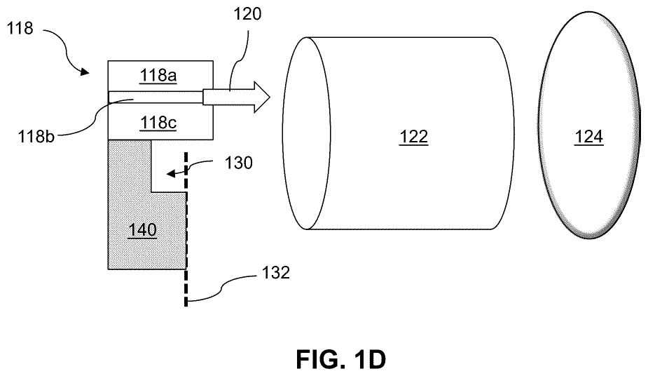

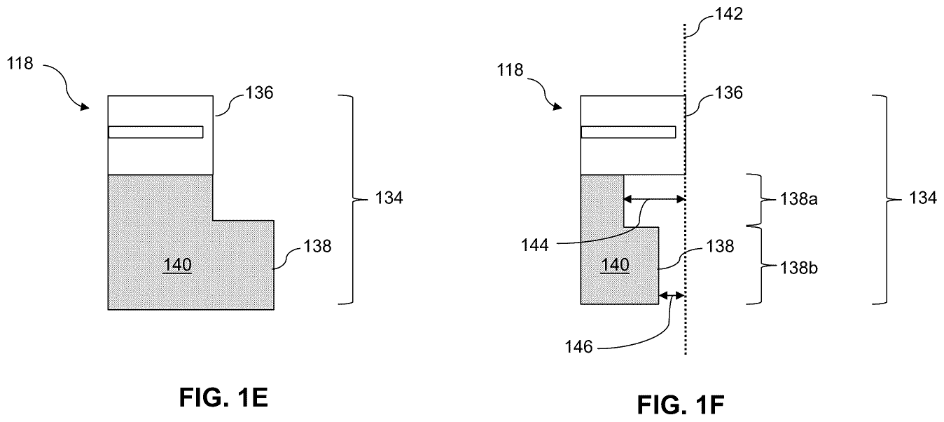

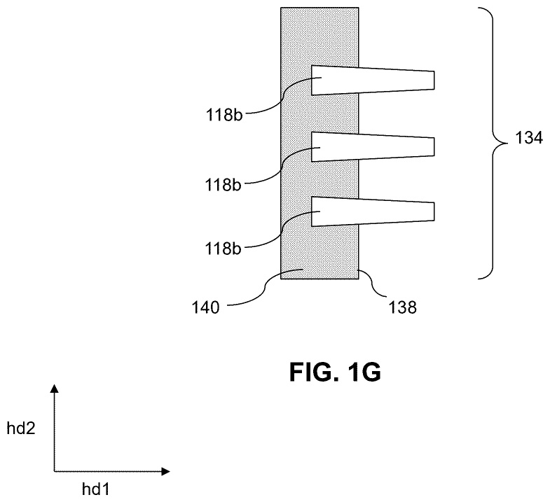

Referring now to figures, FIGS. 1A-1F, which illustrate an example co-packaged optics system 102 including an example optical engine 104.

FIG. 1A is a schematic block diagram of the co-packaged optics system 102. The co-packaged optics system 102 includes a circuit board 106 (for example, a printed circuit board) and a switch application specific integrated circuit (ASIC) 108 (also may be referred to as a first die 108) mounted on the circuit board 106. Optical engines, including the example optical engine 104, may be arranged around the periphery of the circuit board 106 or in any other appropriate arrangement on the circuit board 106. The optical engine 104 may be configured to communicate with the switch ASIC 108 via electrical connections in the circuit board 106.

In general, co-packaged optics includes technology where optical transceivers, typically used for high-speed data transmission in networking applications, may be integrated closely with at least one switch ASIC on a single package or module. The circuit board 106 serves as the foundation for integrating various components of the co-packaged optics system 102. The circuit board 106 provides electrical connections between the switch ASIC 108, the optical engine 104, and in some embodiments, other circuitry.

The switch ASIC 108 is an integrated circuit configured to, for example, handle the switching and routing of data packets within a network. In some embodiments, the switch ASIC 108 processes incoming and outgoing data traffic, manages data flow, and can include features such as buffering, forwarding tables, and network interface controls.

The optical engine 104, in some embodiments, is an optical transceiver module integrated into the co-packaged optics system 102. The optical engine 104 may include, for example, components such as lasers, photodiodes, modulators, and associated circuitry for transmitting and receiving optical signals.

In some embodiments, the use of co-packaged optics reduces latency by minimizing the physical distance between the optical components and the switch ASIC 108, thereby enhancing overall network performance. By integrating optics and electronics closely together, co-packaged optics may also improve power efficiency as compared to related configuration in which optical transceivers are separate. This integration of optics and electronics may, in some embodiments, optimize energy consumption in data centers and high-performance computing environments. Furthermore, co-packaged optics enables higher port densities and increased data throughput, addressing the escalating demands for bandwidth in modern networks.

FIG. 1B is a cross-sectional view of the example optical engine 104. In this example, the optical engine 104 includes an electronic integrated circuit 110 and a photonic component 112 mounted on a silicon substrate 114. The silicon substrate 114 may be mounted on the circuit board 106.

In some embodiments, the electronic integrated circuit 110 in the optical engine 104 may be configured for processing electronic signals, including data modulation, signal amplification, and error correction. The electronic integrated circuit 110 may include drivers for modulating laser diodes, transimpedance amplifiers (TIAs) for amplifying signals received from photodetectors, and various control circuits for managing power and data flow. The electronic integrated circuit 110 can be fabricated using, for example, complementary metal-oxide-semiconductor (CMOS) technology, which allows for high integration density and low power consumption.

In some embodiments, the photonic component 112 includes devices such as lasers, modulators, waveguides, photodetectors, and spot size converters. These components are configured for converting electronic signals into optical signals for transmission and converting received optical signals back into electronic signals. Lasers and modulators generate the optical signals, waveguides route the signals through the photonic circuit, photodetectors convert incoming optical signals to electrical form, and spot size converters adjust the mode field diameter for efficient coupling to optical fibers or other photonic devices.

Both the electronic integrated circuit 110 and the photonic component 112 may be mounted on a silicon substrate 114, which provides a stable platform for integrating electronic and photonic devices. The silicon substrate 114 may be a silicon-on-insulator (SOI) wafer to electrically and optically isolate the active devices from a bulk silicon substrate. The silicon substrate 114 may be shaped and positioned for precise alignment and thermal management for the integrated components.

The optical engine 104 may be optically coupled to one or more optical components 116, facilitating the transfer of optical signals between the optical engine 104 and external devices. The optical components 116 may include elements such as fiber optic cables, optical connectors, micro-optic lenses, and photonic integrated circuits (PICs). The optical coupling mechanism may be configured for efficient alignment and signal transmission, minimizing insertion loss and signal degradation.

For example, fiber optic cables may be directly connected to the optical engine 104 using precision-aligned connectors or splicing techniques, allowing for high-speed data transmission over long distances. Micro-optic lenses may be used to focus and direct the light beams between the optical engine 104 and other photonic devices, enhancing coupling efficiency and signal integrity. Photonic integrated circuits (PICs) may be integrated with the optical engine 104 to perform complex signal processing tasks, such as wavelength multiplexing, switching, and filtering.

The optical coupling may be achieved using various techniques, such as butt-coupling, lens-coupling, or grating couplers, depending on the specific requirements of the application. Butt-coupling involves directly aligning the optical fiber or component with the photonic component edge of the optical engine 104, providing a straightforward and efficient coupling method. Lens-coupling utilizes micro-optic lenses to focus the light from the optical engine 104 into the optical fiber or component, reducing coupling losses. Grating couplers use diffractive structures to couple light between the optical engine 104 and optical fibers, allowing for more flexible alignment and integration.

FIG. 1C is diagram illustrating an example edge coupler 118 for the photonic component 112. The edge coupler 118 includes cladding 118a, a spot size converter 118b, and a buried oxide layer 118c. The edge coupler 118 transmits and receives light 120 to and from optical components such as an optical fiber 122 and lens 124. The edge coupler 118 may be mounted on a silicon substrate 140 internal to the photonic component 112.

The cladding 118a may surround the core of the edge coupler 118 and may be configured for maintaining the confinement of the transmitted and received light within the core by having a lower refractive index than the core. This refractive index difference may be selected such that light is guided along the core through total internal reflection, minimizing signal loss and maintaining the integrity of the transmitted optical signal. The cladding 118a also provides mechanical protection to the core, enhancing the durability and reliability of the edge coupler 118.

The spot size converter 118b is a structure within the edge coupler 118 configured, for example, to gradually adjust the mode field diameter of the optical signal. This gradual adjustment of the mode field diameter of the optical signal may be useful for efficient coupling between the photonic component 112 and external optical fibers or other photonic devices, which may have different mode field diameters. By matching the mode size of the light emitted or received, the spot size converter 118b in some embodiments minimizes coupling losses and maximizes signal transfer efficiency.

The buried oxide layer 118c, also known as the BOX layer, is part of the silicon-on-insulator (SOI) structure and may be configured to provide electrical and optical isolation between the photonic devices and the underlying silicon substrate 114. This electrical and optical isolation, in some embodiments, helps to reduce substrate-induced losses and crosstalk between adjacent photonic components, improving the overall performance of the optical engine 104. In some embodiments, the buried oxide layer 118c also aids in thermal management, dissipating heat generated by the photonic components and maintaining stable operating conditions.

In some embodiments, fabricating the photonic component 112 includes dicing the photonic component 112 along a dicing plane 126 such that a silicon ledge 128 remains in the silicon substrate 140 after the dicing. Dicing the optical engine 104 may include performing a facet etch. In various embodiments, to prevent damage to the spot size converter 118b, it is recommended to keep the dicing plane 126 a certain distance away from the edge coupler 118 during the dicing process. The silicon ledge 128 may be a result of maintaining this distance during the dicing process.

The silicon ledge 128, however, may prevent close positioning of the edge coupler 118 to external optical components. To reduce the lateral dimension of the silicon ledge 128 and enable closer positioning of the edge coupler 118 to external optical components, a further process of etching and dicing the silicon substrate 140 may be performed while preventing damage to the spot size converter 118b.

FIG. 1D is a diagram illustrating the example edge coupler 118 after etching and dicing to remove the silicon ledge 128. The etching creates a recess 130 in the silicon substrate 140, and the subsequent dicing along a dicing plane 132 closer to the photonic component 112 removes a portion of the silicon substrate 140.

FIGS. 1E and 1F are vertical cross-sectional views that illustrate a coupling interface 134 of the edge coupler 118 that faces one or more external optical components. The edge coupler 118 includes a photonic component edge 136 (i.e., a first edge 136) at the coupling interface 134. The silicon substrate 140 comprises a substrate coupling edge 138 at the coupling interface 134.

As shown in FIG. 1E, the substrate coupling edge 138 (i.e., a second edge 138) protrudes beyond the photonic component edge 136 at the coupling interface 134 as a result of the photonic component 112 dicing process. This protrusion limits the spacing between the photonic component edge 136 and an external optical component.

FIG. 1F shows the edge coupler 118 after etching the silicon substrate 140 to create a recess in the silicon substrate 140 under the photonic component edge 136 and dicing the silicon substrate 140 to remove a portion of the silicon substrate 140 such that the photonic component edge 136 protrudes beyond the substrate coupling edge 138 at the coupling interface 134. As a result, the silicon substrate 140 imposes no limitation on the spacing between the photonic component edge 136 and an external optical component.

In some embodiments, the silicon substrate 140 has an L shape in a vertical cross-sectional view. The coupling interface 134 extends along a coupling plane 142. The substrate coupling edge 138 comprises a recess portion 138a distanced from the coupling plane 142 for a first non-zero predetermined distance 144 and an end portion 138b distanced from the coupling plane 142 for a second non-zero predetermined distance 146. The first and second non-zero predetermined distances 144, 146 are different; for example, the recess portion 138a may be farther from the coupling plane 142 than the end portion 138b such that the first non-zero predetermined distance 144 is greater than the second non-zero predetermined distance 146.

FIG. 1G is a top-down see-through view that shows spot size converters 118b over the silicon substrate 140 at the coupling interface 134. Each of the spot size converters 118b extends along a direction from a position above the silicon substrate 140 to a position beyond the substrate edge 138. The width of each of the spot size converters 118b in a second horizontal direction hd2 decreases gradually along as the spot size converters 118b extend in a first horizontal direction hd1.

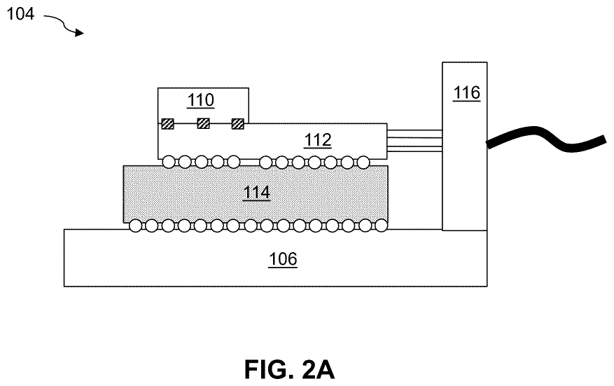

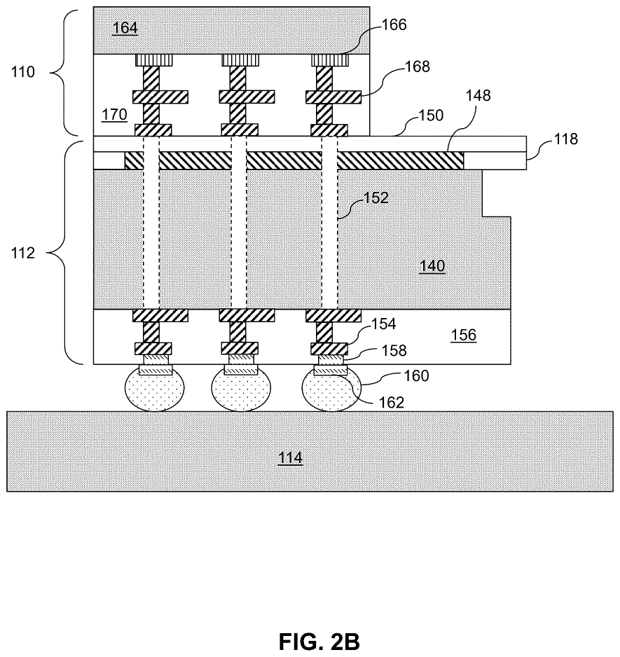

FIG. 2A is a cross-sectional view of an alternative configuration for the optical engine 104. As shown in the example of FIG. 2A, the optical engine 104 includes the electronic integrated circuit 110 mounted on top of the photonic component 112. The photonic component 112 is mounted on the silicon substrate 114, and the silicon substrate 114 is mounted on the circuit board 106.

The embodiment shown in FIG. 1B offers a simpler packaging process but may result in a higher resistance between the electronic integrated component 110 and the photonic component 112 due to the connection through the silicon substrate 114. Alternatively, the embodiment shown in FIG. 2A features lower resistance between the electronic integrated circuit 110 and the photonic component 112, albeit with a more complex packaging process.

For example, the packaging process for the embodiment shown in FIG. 1B may be simplified due to the separation of the electronic and photonic components on the same substrate. In some cases, the components may be tested individually before integration, potentially reducing assembly complexity.

In contrast, the example configuration depicted in FIG. 2A uses a stacking approach that reduces the electrical resistance between the electronic integrated circuit 110 and the photonic component 112 because the direct interface between these components reduces the distance that electrical signals travel. This lower resistance may result in improved performance characteristics, such as reduced power consumption and enhanced signal integrity.

The packaging process for the example configuration depicted in FIG. 2A may be more complex due to the need for precise alignment and bonding of the stacked components. In some embodiments, the direct interface between the electronic integrated circuit 110 and the photonic component 112 may include packaging techniques such as flip-chip bonding or through-silicon vias (TSVs) to ensure reliable electrical connections and thermal management.

In the embodiment shown in FIG. 1B, the electronic integrated circuit 110 and the photonic component 112 are each mounted onto the silicon substrate 114 using, for example, solder balls. The solder balls facilitate the electrical connections between the respective components and the substrate 114. Once these connections are established, the silicon substrate 114, with the electronic and photonic components attached, is mounted onto the circuit board 106 using additional solder balls. The mounting process may include precise placement and reflow soldering to ensure robust connections.

For the embodiment shown in FIG. 2A, the electronic integrated circuit 110 is mounted directly on top of the photonic component 112. This vertical stacking may be achieved using, for example, hybrid bonding, which is a technique in which both electrical and mechanical connects may be achieved simultaneously by combining direct metal-to-metal connections with dielectric bonding between two surfaces. For example, hybrid bonding may include planarization and surface preparation of both surfaces, direct bonding of dielectric materials, and metal-to-metal connections made at metal bonding pads under heat and pressure without the need for additional solder material.

The photonic component 112, now with the electronic integrated circuit 110 mounted on top, is then attached to the silicon substrate 114 using solder balls. Then, the silicon substrate 114 is mounted onto the circuit board 106 using the same solder ball technique. The packaging process for this configuration can include precise alignment and control during the reflow soldering process to ensure reliable and effective connections, given the complexity of the stacked arrangement.

Both configurations as shown in FIGS. 1B and 2A may be useful in certain situations. The embodiment in FIG. 1B offers a simpler assembly process but may encounter performance limitations due to higher resistance. Conversely, the embodiment in FIG. 2A may provide superior electrical performance with lower resistance but may include a more intricate and potentially costly packaging process. Selection between these configurations may depend on the specific application requirements, including considerations of performance, manufacturing capabilities, and cost constraints.

FIG. 2B is a detailed view showing the electronic integrated circuit 110 and the photonic component 112 in accordance with some embodiments. The photonic component 112 may include a waveguide 148 optically coupled to the edge coupler 118 and a dielectric layer 150 over the waveguide 148. The photonic component 112 may include through-silicon vias (TSVs) 152 passing through the substrate 140 for making electrical connections between the electronic integrated component 110 and an external component, for example, the substrate 114 or the circuit board 106.

For example, the photonic component 112 may include metal interconnect structures 154 within one or more dielectric layers 156. The interconnect structures 154 may be connected to conductive pads 158 which are in turn connected to conductive terminals 160. Each of the conductive terminals 160 may provide an electrical connection for a ground or power supply voltage and an external component 114. Each of the conductive terminals 160 may be, for example, a solder ball including a solder region and an intermetallic compound (IMC) region 162 at the interface between the solder and the conductive pads 158.

The electronic integrated circuit 110 may include a substrate 164 and transistors 166 on the substrate 164. The electronic integrated circuit 110 may include metal interconnect structures 168 in one or more dielectric layers 170. The interconnect structures 168 may connect the transistors 116 to the TSVs 152 in embodiments in which the electronic integrated circuit 110 may be bonded to the photonic component 112.

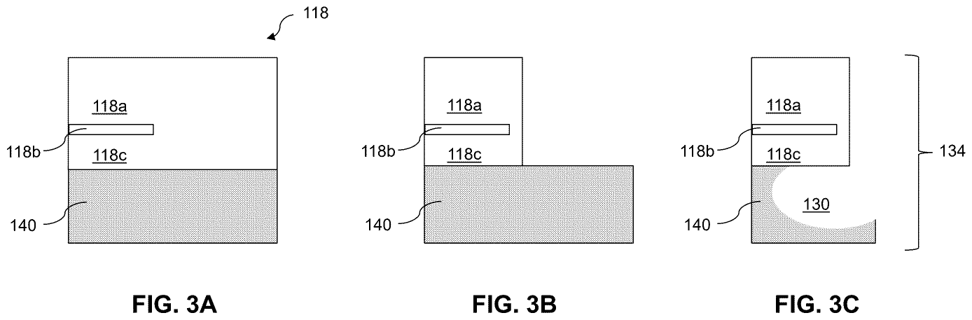

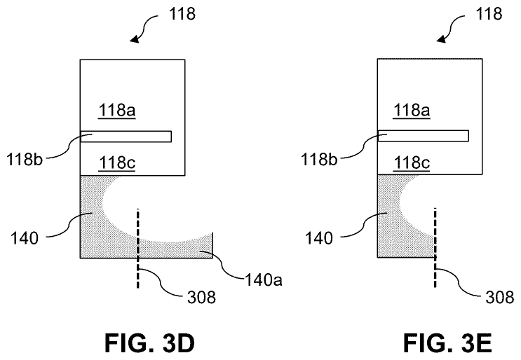

FIGS. 3A-3E illustrate an example process for fabricating an optical engine 104 having the edge coupler 118. FIGS. 3A-3E show cross-sectional views of the optical engine during various stages of the process.

FIG. 3A shows the silicon substrate 140 and the edge coupler 118 mounted on the silicon substrate 140. The edge coupler 118 includes cladding 118a, the silicon spot size converter 118b, and the buried oxide layer 118c.

FIG. 3B shows the edge coupler 118 after performing a facet etch. The facet etch may be useful, for example, for creating a clean and smooth optical interface, which can aid in minimizing coupling losses related to interfacing with external optical components, such as optical fibers.

In some embodiments, the facet etch includes masking, etching, and cleaning. A photolithographic mask is applied to protect certain areas of the edge coupler 118 during the etching process. The mask precisely defines the regions where material removal is desired, ensuring that the etching occurs only at the facet.

The etching process itself may be performed using dry etching techniques, such as reactive ion etching (RIE) or inductively coupled plasma (ICP) etching. These dry etching techniques allow for highly anisotropic etching, which may achieve vertical sidewalls and a smooth surface finish. The choice of etching gases and process parameters is based on achieving the desired etch profile and surface quality.

After etching, the residual mask material and any etch byproducts are removed through a cleaning process. This cleaning process may be useful, for example, to ensure that the facet is free of contaminants, which could otherwise degrade the optical performance.

Alternatives to the described facet etch process may involve different etching techniques or materials. For instance, wet etching may be used for some applications, though it typically offers less control over the etch profile compared to dry etching. Additionally, laser-assisted etching or focused ion beam (FIB) milling may be used for creating facets in specific scenarios where precision and surface quality are paramount.

FIG. 3C shows the edge coupler 118 and silicon substrate 140 after performing an undercut using sulfur hexafluoride (SF₆), leaving a recess 130 in the shape of a semicircular notch in the silicon substrate 140 at the coupling interface 134 to one or more external optical components.

In the example shown in FIG. 3C, sulfur hexafluoride (SF₆) is chosen as the etching gas due to its high selectivity for silicon, enabling precise control over the etch depth and profile. In general, any isotropic etch, such as SF₆, tetramethylammonium hydroxide (TMAH), or potassium hydroxide (KOH), can be used for undercutting and creating the recess 130. TMAH etches at specific angles based on the orientation of the Si crystal, but it has a slower etch rate, resulting in a longer process time. On the other hand, SF₆ has a faster etch rate, but it may not allow for control over the profile based on the crystal's lattices.

In some examples, the undercut begins with the application of a protective mask to define the area for the undercut etch. This mask ensures that only the desired regions of the silicon substrate 140 are exposed to the etching gas, preserving the integrity of the remaining structure.

The etching is then carried out in a controlled environment, where SF₆ gas is introduced into a plasma etching chamber. The SF₆ molecules dissociate in the plasma, forming reactive fluorine species that chemically react with the exposed silicon, etching the exposed silicon away to form the circular recess 130.

The etching parameters, such as gas flow rate, chamber pressure, and RF power, may be selected to achieve the desired recess profile. Once the etching process is complete, the protective mask may be removed, and the newly formed circular recess 130 may be cleaned to remove any residual etching byproducts or contaminants.

FIGS. 3D-3E illustrate the removal of a portion 140a of the silicon substrate 140 using stealth dicing. FIG. 3D shows the formation of a scribe line along a dicing plane 308 using a laser. FIG. 3E shows cleaving the silicon substrate 140 along the scribe line to remove the portion 140a of the silicon substrate 140.

Stealth dicing utilizes a focused laser beam to create subsurface modifications within the silicon substrate 140. The laser, operating at a specific wavelength that penetrates the silicon, induces localized changes within the material without affecting the surface. The laser beam may be precisely controlled to follow the intended dicing plane 308, creating a continuous scribe line beneath the surface. This scribe line includes a series of micro-cracks or modified zones within the silicon lattice, which serve as initiation points for subsequent cleaving.

In FIG. 3E, the silicon substrate 140 may be cleaved along the pre-formed scribe line to remove the portion 140a. The cleaving process exploits the subsurface modifications introduced by the laser scribing. Mechanical force may be applied to the substrate, typically using a tool or by exerting pressure, causing the substrate to fracture cleanly along the scribe line. The stealth dicing method enables a precise and controlled separation, minimizing mechanical stress and potential damage to the remaining structure. The resulting edge may be smooth and well-defined.

Stealth dicing may, in some cases, offer several advantages over related mechanical dicing methods. Stealth dicing may reduce the generation of particles and debris, as the laser-induced modifications occur subsurface and the actual cleaving generates minimal mechanical disruption. Such cleanliness may be beneficial in maintaining the integrity of delicate photonic components and reducing the need for extensive post-dicing cleaning processes.

Alternative dicing techniques include mechanical sawing or plasma dicing. Mechanical sawing uses a diamond-tipped blade to physically cut through the substrate, which can introduce mechanical stress and debris but is widely used for its simplicity and effectiveness. Plasma dicing, on the other hand, employs reactive plasma to etch through the substrate along defined lines, offering a stress-free and clean dicing process but requiring more complex equipment and process control.

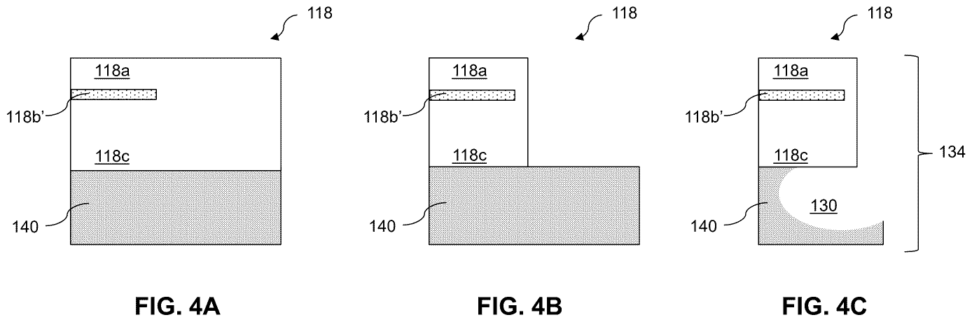

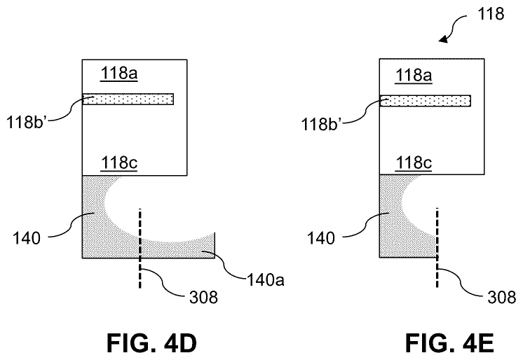

FIGS. 4A-4E illustrate an example process for fabricating an optical engine 104 having an edge coupler 118 with a silicon nitride (SiN) spot size converter 118b′. Silicon and silicon nitride spot size converters are both used in photonic integrated circuits to manage the transition of optical modes between components, such as fibers and waveguides. Each material offers distinct advantages and disadvantages based on their physical properties and integration capabilities.

Silicon spot size converters leverage the high refractive index of silicon, which allows for tight optical confinement and efficient mode conversion. The high refractive index of silicon enables silicon waveguides to achieve smaller mode field diameters, which may be advantageous for compact photonic circuits. Silicon spot size converters may efficiently couple light from small silicon waveguides to larger optical fibers by gradually expanding the mode size. The high index contrast between silicon and its cladding materials, such as silicon dioxide (SiO2), allows for precise control over the optical mode shape and size. Additionally, silicon is compatible with standard complementary metal-oxide-semiconductor (CMOS) fabrication processes, enabling large-scale integration and mass production of photonic devices.

However, silicon spot size converters may also have disadvantages. The high refractive index contrast, while beneficial for tight confinement, may lead to increased sensitivity to fabrication imperfections, such as sidewall roughness and dimensional variations. This increased sensitivity to fabrication imperfections may result in higher optical losses and reduced performance consistency across devices. Silicon may also be more prone to nonlinear optical effects, such as two-photon absorption and free-carrier absorption, which may limit the performance of high-power photonic applications.

Alternatively, silicon nitride (SiN) spot size converters 118b′ offer different advantages and disadvantages due to their material properties. SiN has a lower refractive index than silicon, resulting in less confined optical modes. This lower index contrast may be beneficial for achieving low-loss transitions between waveguides and optical fibers, as the mode overlap with the fiber can be better optimized. SiN is less sensitive to fabrication imperfections compared to silicon, leading to more robust and consistent device performance. The lower refractive index may also reduce nonlinear optical effects, making SiN suitable for high-power applications.

However, the use of SiN spot size converters 118b′ may in some embodiments present challenges. The lower refractive index may result in larger mode field diameters, which may necessitate more space for the waveguides and converters, potentially increasing the overall footprint of the photonic circuit. This larger mode size may also limit the integration density of SiN-based devices. Additionally, SiN is not as widely integrated into standard CMOS processes as silicon, which may complicate fabrication and increase production costs.

FIG. 4A shows the edge coupler 118 having the SiN spot size converter 118b′. FIG. 4B shows the edge coupler 118 after the facet etch. FIG. 4C shows the silicon substrate 140 after undercutting to create the recess 130. FIGS. 4D-4E show the stealth dicing process to remove the portion 140a of the silicon substrate 140.

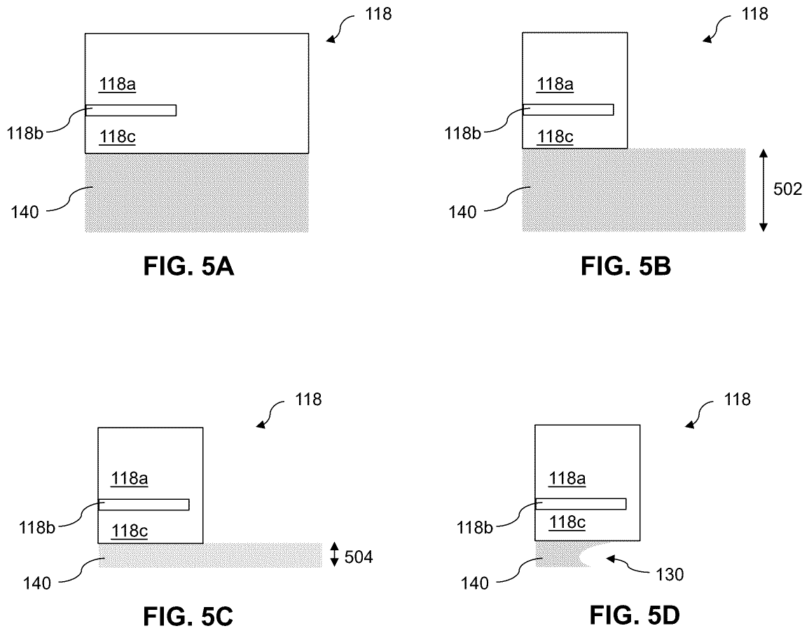

FIGS. 5A-5D illustrate another example process for fabricating an optical engine 104 having an edge coupler 118. FIGS. 5A-5D show vertical cross-sectional views of the optical engine 104 during various stages of the process.

FIG. 5A shows the silicon substrate 114 and the edge coupler 118 mounted on the silicon substrate 140. The edge coupler 118 includes the cladding 118a, the spot size converter 118b, and the buried oxide layer 118c. FIG. 5B shows the edge coupler 118 after performing the facet etch.

FIG. 5C shows the edge coupler 118 after performing backside grinding on the silicon substrate 140. The thickness 504 of the silicon substrate 140 after backside grinding is smaller than the thickness 502 of the silicon substrate 140 prior to backside grinding as shown in FIG. 5B.

Backside grinding is a mechanical process used to reduce the thickness of the silicon substrate 140 by removing material from the backside, or bottom surface, of the wafer. This process may include securing the silicon wafer on a support carrier, typically with an adhesive, and then grinding the exposed backside using a rotating abrasive wheel. The grinding process may be controlled to achieve the desired final thickness with high precision. Control of the grinding parameters is used to prevent damage, such as micro-cracks or warping, which may compromise the structural integrity and performance of the silicon substrate 140 and the integrated components.

A thinner backside of silicon may be desired, for instance, in embodiments in which there are heater devices in the photonic component. A thinner backside of silicon may be useful to prevent heat dissipation that could potentially compromise the efficiency of the heaters.

Alternatively, performing backside grinding may be undesirable in embodiments in which enhanced heat dissipation is useful. For example, in embodiments that include placing an on-chip laser on the silicon substrate 140, enhanced heat dissipation may be useful to bolster the stability of the laser chip.

FIG. 5D shows the edge coupler 118 after performing undercutting and dicing to create a circular recess 130 in the silicon substrate 140. For example, performing undercutting may include undercutting using SF₆ or TMAH and the dicing may include stealth dicing or laser dicing.

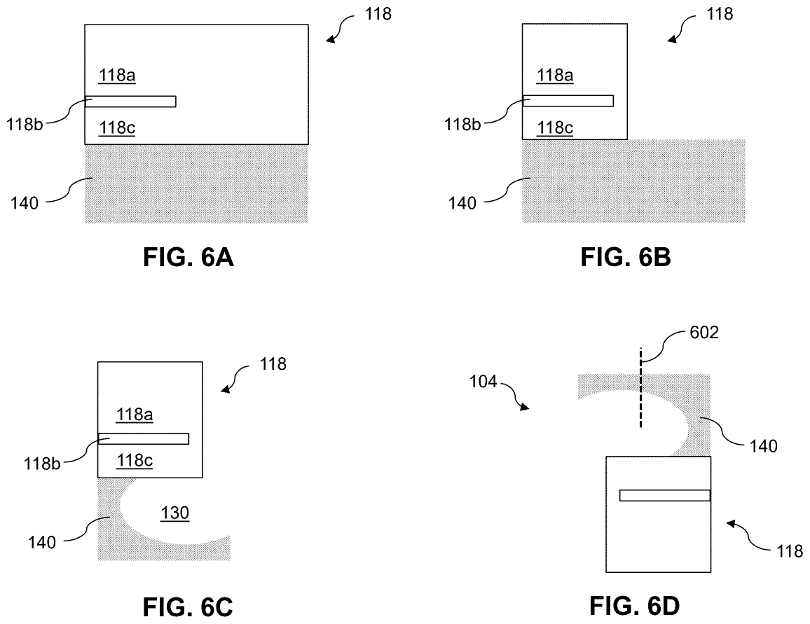

FIGS. 6A-6D illustrate another example process for fabricating an optical engine 104 having an edge coupler 118. FIGS. 6A-6D show vertical cross-sectional views of the optical engine during various stages of the process.

FIG. 6A shows the silicon substrate 140 and the edge coupler 118 mounted on the silicon substrate 140. The edge coupler 118 includes the cladding 118a, the spot size converter 118b, and a buried oxide layer 118c. FIG. 6B shows the edge coupler 118 after performing a facet etch process. FIG. 6C shows the edge coupler 118 and silicon substrate 140 after performing an undercut using sulfur hexafluoride (SF₆), leaving a recess 130 shaped as a semicircular notch in the silicon substrate 140.

FIG. 6D shows the optical engine 104 after inverting the optical engine 104 upside down and preparing to dice the silicone substrate 140 using a laser. The laser may be, for example, an ultraviolet (UV) pulsed laser. In some embodiments, the laser may be an excimer laser or a UV Nd: YAG laser.

Excimer lasers with deep ultraviolet wavelengths (around 248 nm) are commonly used due to their short pulse duration and high peak power. These properties minimize heat affected zones and enable clean material removal.

During the dicing process, the inverted optical engine 104 may be mounted on a high-precision stage, and the laser beam is then focused onto the silicon substrate 140 along a dicing plane 602 using, for example, mirrors and lenses, following a programmed pattern to define the final shape. Each laser pulse removes a small amount of silicon substrate 140 material, effectively dicing the silicon substrate 140 along the desired dicing plane 602.

After the dicing process is complete, compressed air or another appropriate method may be used to remove any debris and separated pieces. By controlling the laser parameters like pulse energy and scan speed, the dicing process may ensure clean cuts with minimal damage to the remaining material, especially the edge coupler 118.

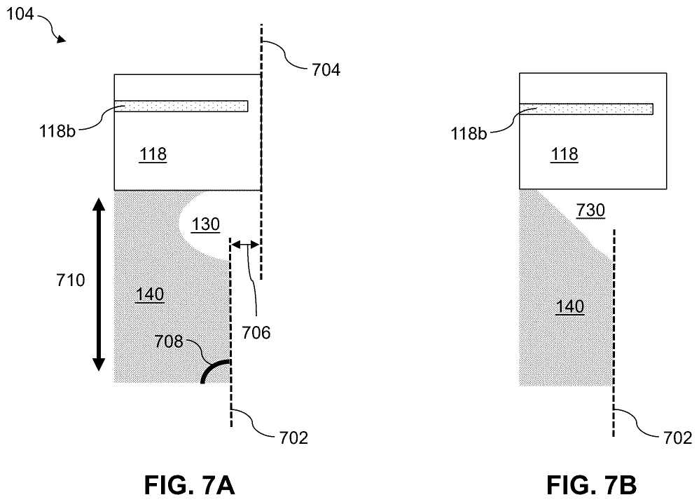

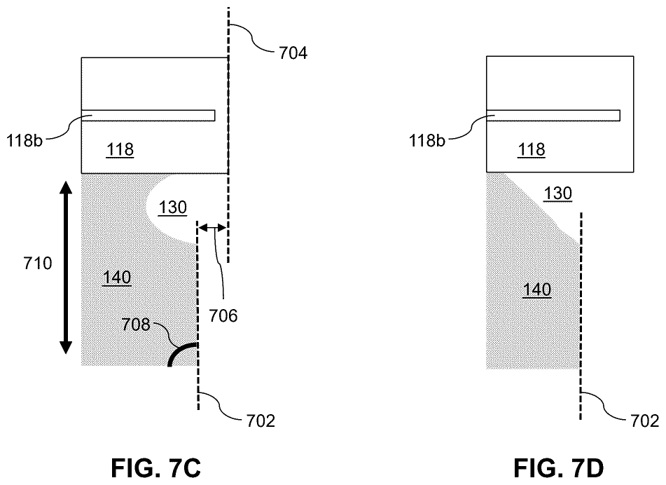

FIGS. 7A-7D illustrate features of the optical engine 104 after removal of a silicon ledge. FIGS. 7A-7D show vertical cross-sectional views of the optical engine 104.

FIG. 7A shows the edge coupler 118 with the SiN spot size converter 118b′. The silicon substrate 140 has been diced along a first dicing plane 702, and the edge coupler 118 has been diced along a second dicing plane 704, leaving a gap 706 between the first plane 702 and the second plane 704. The gap 706 is ≥0 such that the silicon substrate 140 does not impose a limitation on the spacing between the edge coupler 118 and an external optical component.

The first dicing plane 702 may, in general, be configured to follow an arbitrary angle 708 with respect to the bottom of the silicon substrate 140. Moreover, the silicon substrate 140 may have any appropriate thickness 710. By controlling the angle 708, thickness 710, and depth and shape of the recess 130, the shape of the remaining silicon substrate 140 may be controlled to form various appropriate structures.

FIG. 7B shows the edge coupler 118 after TMAH undercutting has defined a recess 730 in a triangular shape in the silicon substrate 140. The parameters of the TMAH undercutting can be controlled to create various other appropriate shapes for the recess 730.

For example, a higher concentration of TMAH generally leads to a faster etch rate, creating a wider and deeper triangular recess 730. Conversely, a lower concentration results in a slower etch and a shallower, narrower triangular recess 730. The temperature of the TMAH solution may also be varied or selected to produce a target recess 730 shape. Higher temperatures typically accelerate the etch rate, similar to using a higher concentration. However, excessively high temperatures may lead to unwanted effects like increased sidewall etching.

Longer exposure times allow for a deeper etch, creating a more pronounced triangular shape for the recess 730. Conversely, shorter exposure times result in a shallower etch. In some cases, a masking material (not shown) may be applied to specific areas of the silicon substrate 140 before TMAH exposure. This mask protects desired regions from the etching process, allowing for more intricate recess shapes beyond simple geometries. The pattern and thickness of the mask will influence the final profile of the etched recess 730.

FIGS. 7C-7D show the edge coupler 118 with the silicon spot size converter 118b. The same gap 706 is produced by etching and dicing and the same shapes may be produced in the silicon substrate 140.

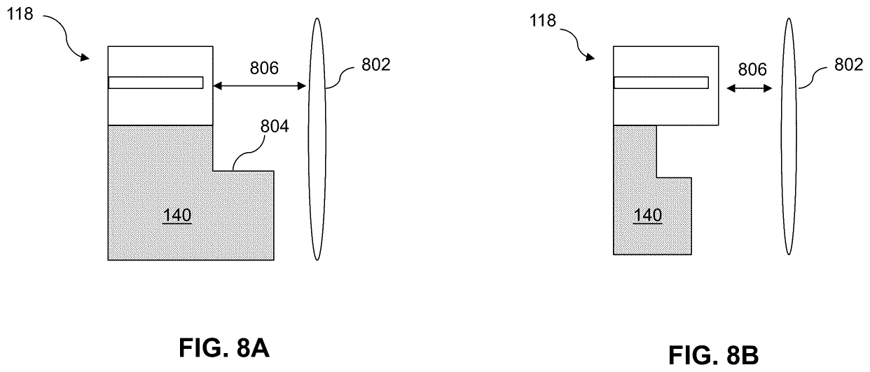

FIGS. 8A-8B illustrate an example process for aligning an edge coupler 118 with an example optical component 802. In this example, the optical component 802 is a microlens. In general, the process may be used for alignment with any appropriate optical component or system of optical components.

FIG. 8A is a vertical cross-sectional view of the silicon substrate 140 and edge coupler 118. A silicon ledge 804 is present in the silicon substrate 140. In instances in which the alignment is performed while the silicon ledge 804 is present, then the spacing 806 between the edge coupler 118 and the microlens 802 may be limited by the silicon ledge 804 because the silicon substrate 140 will contact the microlens 802 as the edge coupler 118 is brought towards the microlens 802.

FIG. 8B is a cross-sectional view of the silicon substrate 140 and edge coupler 118 after the silicon ledge 804 has been removed by etching and dicing. Now, the edge coupler 118 may be aligned with a closer spacing 806 with the microlens 802 such that the spacing 806 between the edge coupler 118 and the microlens 802 is not limited by the silicon ledge 804.

The edge coupler 118 as shown in FIG. 8B may be positioned closer (i.e., smaller spacing 806) to the microlens 802, which may be useful for creating superior optical coupling in some cases. For example, in some embodiments, the spacing 806 between the edge coupler 118 and the microlens 802 is less than 10 μm.

The following discussion now refers to a number of methods and method steps. Although the method steps are discussed in specific orders or are illustrated in a flow chart as being performed in a particular order, no order is required unless expressly stated or required because a step is dependent on another step being completed prior to the step being performed.

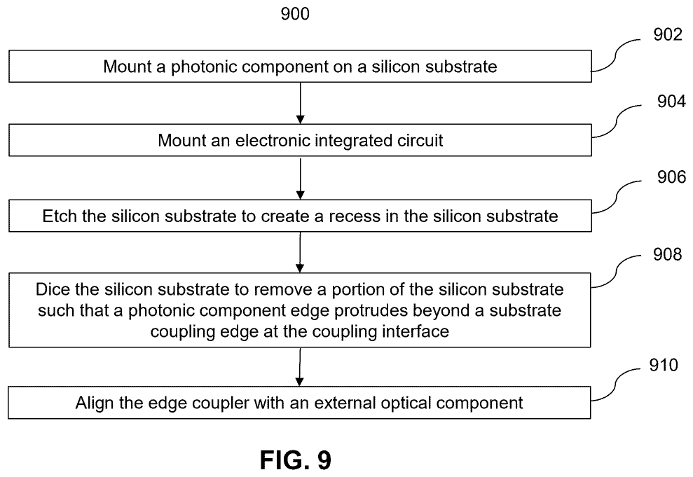

Embodiments are now described in connection with FIG. 9, which illustrates a flow diagram of an example method 900 for fabricating an optical engine 104 according to some embodiments of the present disclosure.

In an embodiment method 900, step 902 comprises mounting a photonic component 112 on a silicon substrate 114 to form the optical engine 104. The photonic component 112 may comprise an edge coupler 118 and a coupling interface 134 configured to interface with one or more external optical components 802. The edge coupler 118 may comprise a photonic component edge 136 at the coupling interface 134. The silicon substrate 140 comprises a substrate coupling edge 138 at the coupling interface 134. In some embodiments, the edge coupler 118 may comprise a spot size converter 118b, 118b′, a buried oxide layer 118c, and cladding 118a.

The substrate coupling edge 138 protrudes beyond the photonic component edge 136 at the coupling interface 134. For example, in some embodiments, fabricating the optical engine 104 comprises performing a facet etch such that the substrate coupling edge 138 protrudes beyond the photonic component edge 136 at the coupling interface 134.

In an embodiment method, step 904 includes mounting an electronic integrated circuit 110. In some embodiments, the method 900 includes mounting an electronic integrated circuit 110 on the silicon substrate 114 adjacent to the photonic component 112. In some embodiments, the method 900 includes mounting an electronic integrated circuit 110 on top of the photonic component 112.

In an embodiment method, step 906 comprises etching the silicon substrate 140 to create a recess 130 in the silicon substrate 140 under the photonic component edge 136. In some embodiments, etching the silicon substrate 140 to create the recess 130 in the silicon substrate 140 under the photonic component edge 136 comprises undercutting the silicon substrate 140 using sulfur hexafluoride (SF₆). Undercutting the silicon substrate 140 using sulfur hexafluoride (SF₆) may result in a semicircular notch 130 formed in the silicon substrate 140 underneath the photonic component edge 136. In some embodiments, etching the silicon substrate 140 to create the recess 130 in the silicon substrate 140 under the photonic component edge 136 comprises undercutting the silicon substrate 140 using tetramethylammonium hydroxide (TMAH).

In an embodiment method, step 908 comprises dicing the silicon substrate 140 to remove a portion 140a of the silicon substrate 140 such that the photonic component edge 136 protrudes beyond the silicon substrate coupling edge 138 at the coupling interface 134. In some embodiments, dicing the silicon substrate 140 to remove the portion 140a of the silicon substrate 140 comprises: forming at least one scribe line on the silicon substrate 140 using a laser; and cleaving the silicon substrate 140 along the scribe line to remove the portion of the silicon substrate 140. In some embodiments, dicing the silicon substrate 140 to remove the portion of the silicon substrate 140 comprises performing laser dicing.

In an embodiment method, step 910 comprises aligning the edge coupler 118 with an external optical component (e.g., lens 802). The spacing 806 between the edge coupler 118 and the external optical component is not limited by the protruding silicon substrate 804.

The various embodiments disclosed herein may provide various advantages and improvements. For example, various embodiments may remove a protruding silicon ledge 804 of an optical engine 104 by etching and dicing. As a result, the optical engine 104 may be positioned closer to an optical component since the protruding silicon ledge 804 may no longer contact the optical component.

Referring to the various figures, a method 900 for fabricating a semiconductor package may be provided, the method may include the operations of: mounting a photonic component 112 on a silicon substrate 114 to form an optical engine 104, wherein: photonic component 112 may include an edge coupler 118 and a coupling interface 134 configured to interface with one or more external optical components 802; the edge coupler 118 may include a first edge 136 at the coupling interface 134; a silicon substrate 140 may include a second edge 138 at the coupling interface; the method may further include the operations of removing a portion of the silicon substrate 140 such that the first edge 136 protrudes beyond the second edge 138 at the coupling interface 134.

In one embodiment, the method may include performing a facet etch. In one embodiment, the method may include etching the silicon substrate 140 to create a recess 130 in the silicon substrate 140 under the first edge 136. In one embodiment, etching the silicon substrate 140 may include undercutting the silicon substrate 140 using sulfur hexafluoride. In one embodiment, undercutting the silicon substrate 140 using sulfur hexafluoride forms a semicircular notch 130 in the silicon substrate 140 underneath the first edge 136. In one embodiment, etching the silicon substrate 140 to create the recess 130 in the silicon substrate 140 under the first edge 136 may include undercutting the silicon substrate 140 using tetramethylammonium hydroxide. In one embodiment, the method may include dicing the silicon substrate 140 to remove the portion of the silicon substrate 140 by: forming at least one scribe line on the silicon substrate 140 using a laser; and cleaving the silicon substrate 140 along the scribe line to remove the portion of the silicon substrate 140. In one embodiment, dicing the silicon substrate 140 to remove the portion of the silicon substrate comprises performing laser dicing. In one embodiment, the method may also include mounting an electronic integrated circuit 110 on the silicon substrate 140 adjacent to the photonic component 112. In one embodiment, the method may also include mounting an electronic integrated circuit 110 on top of the photonic component 112. In one embodiment, the edge coupler 118 may include a spot size converter (SSC) 118b, a buried oxide layer 118c, and cladding 118a.

According to another aspect of the present disclosure, a semiconductor package 104 may be provided. The semiconductor package 104 may include: a silicon substrate 140; and a photonic component 112 mounted on the silicon substrate 140, wherein: the photonic component 112 includes an edge coupler 118 and a coupling interface 134 configured to interface with one or more external optical components 102; the edge coupler 118 may include a photonic component edge 136 at the coupling interface 134; the silicon substrate 114 may include a substrate coupling edge 138 at the coupling interface 134; the photonic component edge 136 protrudes beyond the substrate coupling edge 138 at the coupling interface 134; and a shape of the silicon substrate 114 comprises a semicircular notch underneath the photonic component edge 136. The semiconductor package 104 may include a conductive terminal 160 providing an electrical connection for a ground or power supply voltage between the semiconductor package 104 and an external component 114, and the conductive terminal 160 may include a solder region and an intermetallic compound (IMC) region 162.

In one embodiment, the coupling interface extends along a coupling plane 142, the substrate coupling edge 138 comprises a recess portion 138a distanced from the coupling plane 142 by a first non-zero predetermined distance 144 and an end portion 138b distanced from the coupling plane 142 by a second non-zero predetermined distance 146, and the first and second non-zero predetermined stances 144, 146 are different. In one embodiment, the edge coupler 118 may include a spot size converter (SSC) 118b. In one embodiment, the edge coupler 118 may further include a buried oxide layer 118c and cladding 118a. In one embodiment, the optical engine 104 may also include an electronic integrated circuit 110 mounted on the silicon substrate 114 adjacent to the photonic component 112. In one embodiment, the optical engine 104 may also include an electronic integrated circuit 110 mounted on top of the photonic component 112. In one embodiment, the edge coupler 118 may include a spot size converter (SSC) 118b, a buried oxide layer 118c, and cladding 118a.

According to another aspect of the present disclosure, a photonic semiconductor package 104 comprises: a silicon substrate 140; and a photonic component 112 mounted on the silicon substrate 140, wherein the photonic component 112 includes an edge coupler 118 and a coupling interface 134 configured to interface with one or more external optical components 102, wherein the edge coupler 118 includes a photonic component edge 136 at the coupling interface 134, wherein the silicon substrate 140 comprises a substrate edge 138 at the coupling interface 134; and wherein, from a top view of the photonic semiconductor package 104, the edge coupler 118 extends along a direction from a position above the silicon substrate 140 to a position beyond the substrate edge 138, and the width of the edge coupler 118 decreases gradually along the direction.

In an embodiment, the photonic semiconductor package may include an electronic integrated circuit 110 hybrid bonded to a top of the photonic component 112. In an embodiment, the photonic semiconductor package may include one or more through-silicon vias (TSVs) 152 electrically connecting one or more transistors 166 of the electronic integrated circuit 110 to an external component 114. In an embodiment, the photonic semiconductor package 112 may include one or more interconnect structures 154 electrically connecting the TSVs 152 to one or more conductive pads 158. In an embodiment, the photonic semiconductor package 112 may include one or more conductive terminals 160 over the conductive pads 158.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating a semiconductor package, the method comprising:
mounting a photonic component on a silicon substrate, wherein:
the photonic component comprises an edge coupler and a coupling interface configured to interface with an external optical component;
the edge coupler comprises a first edge at the coupling interface; and
the silicon substrate comprises a second edge at the coupling interface; and
removing a portion of the silicon substrate such that the first edge protrudes beyond the second edge at the coupling interface.

2. The method of claim 1, comprising performing a facet etch and etching the silicon substrate to create a recess in the silicon substrate under the first edge.

3. The method of claim 2, wherein etching the silicon substrate comprises undercutting the silicon substrate using sulfur hexafluoride.

4. The method of claim 3, wherein undercutting the silicon substrate using sulfur hexafluoride forms a semicircular notch in the silicon substrate underneath the first

5. The method of claim 1, wherein etching the silicon substrate to create the recess in the silicon substrate under the first edge comprises undercutting the silicon substrate using tetramethylammonium hydroxide.

6. The method of claim 1, comprising dicing the silicon substrate to remove a portion of the silicon substrate by:
forming at least one scribe line on the silicon substrate using a laser; and
cleaving the silicon substrate along the scribe line to remove the portion of the silicon substrate.

7. The method of claim 1, wherein removing the portion of the silicon substrate comprises performing laser dicing.

8. The method of claim 1, comprising mounting an electronic integrated circuit on the silicon substrate adjacent to the photonic component.

9. The method of claim 1, comprising mounting an electronic integrated circuit on top of the photonic component.

10. The method of claim 1, wherein the edge coupler comprises a spot size converter (SSC), a buried oxide layer, and cladding.

11. A semiconductor package comprising:
a silicon substrate; and
a photonic component mounted on the silicon substrate, wherein:
the photonic component comprises an edge coupler and a coupling interface configured to interface with one or more external optical components;
the edge coupler comprises a photonic component edge at the coupling interface;
the silicon substrate comprises a substrate coupling edge at the coupling interface;
the photonic component edge protrudes beyond the substrate coupling edge at the coupling interface; and
a shape of the silicon substrate comprises a semicircular notch underneath the photonic component edge; and
a conductive terminal providing an electrical connection for a ground or power supply voltage between the semiconductor package and an external component, wherein the conductive terminal includes a solder region and an intermetallic compound (IMC) region.

12. The semiconductor package of claim 11, wherein the coupling interface extends along a coupling plane, the substrate coupling edge comprises a recess portion distanced from the coupling plane by a first non-zero predetermined distance and an end portion distanced from the coupling plane by a second non-zero predetermined distance, and the first and second non-zero predetermined distances are different.

13. The semiconductor package of claim 12, wherein the edge coupler comprises a spot size converter (SSC), a buried oxide layer, and cladding.

14. The semiconductor package of claim 11, comprising an electronic integrated circuit mounted on the silicon substrate adjacent to the photonic component.

15. The semiconductor package of claim 11, comprising an electronic integrated circuit mounted on top of the photonic component.

16. A photonic semiconductor package comprising:
a silicon substrate; and
a photonic component mounted on the silicon substrate,
wherein the photonic component comprises an edge coupler and a coupling interface configured to interface with one or more external optical components,
wherein the edge coupler comprises a photonic component edge at the coupling interface,
wherein the silicon substrate comprises a substrate edge at the coupling interface,
wherein, from a top view of the photonic semiconductor package, the edge coupler extends along a direction from a position above the silicon substrate to a position beyond the substrate edge, and
wherein the width of the edge coupler decreases gradually along the direction.

17. The photonic semiconductor package of claim 16, comprising an electronic integrated circuit hybrid bonded to a top of the photonic component.

18. The photonic semiconductor package of claim 17, wherein the photonic component comprises one or more through-silicon vias (TSVs) electrically connecting one or more transistors of the electronic integrated circuit to an external component.

19. The photonic semiconductor package of claim 18, wherein the photonic component comprises one or more interconnect structures electrically connecting the TSVs to one or more conductive pads.

20. The photonic semiconductor package of claim 19, wherein the photonic component comprises one or more conductive terminals over the conductive pads.
